(19) United States
(12) Patent Application Publication
(10) Pub. No.: US 2014/0139247 A1
(43) Pub. Date: May 22, 2014

(54) INTERPOSER APPARATUS AND METHODS

(71) Applicants: Youngseok Oh, Portland, OR (US); Joe F. Walczyk, Tigard, OR (US)

(72) Inventors: Youngseok Oh, Portland, OR (US); Joe F. Walczyk, Tigard, OR (US)

(21) Appl. No.: 13/684,149

(22) Filed: Nov. 21, 2012

(51) Int. Cl. G01R 1/04; B21D 22/02; G01R 31/26

(52) U.S. Cl. CPC G01R 1/0491; G01R 31/2601; B21D 22/02
USPC 324/750.24; 72/377

(57) ABSTRACT

Embodiments of the present disclosure describe interposer apparatus and methods for their fabrication and use. In some embodiments, an interposer includes a first frame having a first opening, a second frame having a second opening, and a body frame, disposed between the first frame and the second frame. A first end portion of a pin is disposed in the first opening, a second end portion of the pin is disposed in the second opening, and a body portion of the pin is disposed in the body opening between the first and second frames. Other embodiments may be described and/or claimed.

### FIELD

Embodiments of the present disclosure generally relate to the field of electrical devices, and more particularly, to techniques and configurations for device interconnects and testing.

### BACKGROUND

Electrical device manufacturing processes often include a device testing phase during which electrical connections are made between a device-under-test (DUT), such as an integrated circuit (IC) package, and test equipment (TE). In some circumstances, an interposer apparatus is positioned between electrical probes of the TE and the electrical contact points of the DUT to provide electrical pathways between the TE and DUT.

Because DUTs may exhibit surface variability (e.g., due to manufacturing tolerances and warping of substrates), some mechanical compliance in the interposer assembly may be desired to improve the reliability of the connection between the TE and DUT. Some existing interposers use several thousand sets of multiple helical springs made of conductive metal and confined in polymer tubing to provide mechanically compliant electrical pathways between the TE and DUT. Because of the high part count and complexity of such designs, existing interposers may be difficult and expensive to manufacture and therefore limited to a narrow range of temporary interconnect applications.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1A and 1B illustrate cross-section side views of an interposer before and after operational contact with TE and a DUT, in accordance with some embodiments.

FIG. 2A illustrates an exploded perspective view of an interposer with multiple pins, in accordance with some embodiments.

FIGS. 2B and 2C illustrate cross-section side views of the interposer of FIG. 2A, in accordance with some embodiments.

FIG. 3 is a flow diagram of a method of positioning an interposer relative to first and second electrical devices, in accordance with some embodiments.

FIGS. 4A-4G schematically illustrate an interposer subsequent to various fabrication operations, in accordance with some embodiments.

FIG. 5A illustrates a side view of a pin fabrication assembly, in accordance with some embodiments.

FIGS. 5B-5E illustrate cross-section top views of components of the pin fabrication assembly of FIG. 5A, in accordance with some embodiments.

FIG. 6 is a flow diagram of a method of fabricating a pin for an interposer, in accordance with some embodiments.

FIG. 7 schematically illustrates a computing device, in accordance with some embodiments.

### DETAILED DESCRIPTION

Embodiments of the present disclosure describe interposer apparatus and methods for their fabrication and use. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

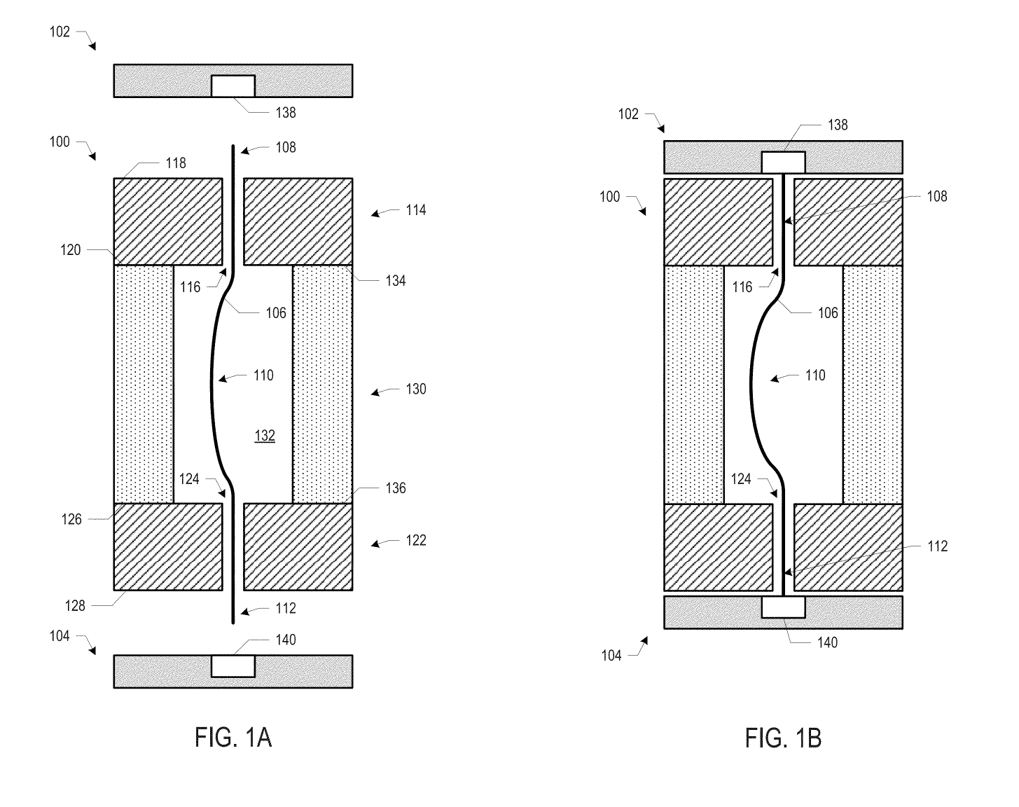

FIGS. 1A and 1B illustrate cross-section side views of an interposer 100 before and after operational contact with TE 102 and a DUT 104, in accordance with some embodiments. In some embodiments, TE 102 may include a set of electrical probes (e.g., arranged in an array with approximately 100 microns pitch-to-pitch, not shown) coupled to a space transformer (e.g., a ceramic substrate with a thin film routing layer, not shown) that fans out the tight pitch probe set for contact with interposer 100. TE 102 may be part of high volume manufacturing (HVM) sort and test tooling, for example. In some embodiments, DUT 104 may include a die, an IC package and/or a printed circuit board (PCB).

Interposer 100 may include a pin 106 having a first end portion 108, a body portion 110, and a second end portion 112. Body portion 110 may be disposed between first end portion 108 and second end portion 112, as shown. In some embodiments, pin 106 is a materially contiguous, unitary structure; in other embodiments, pin 106 includes two or more sub-components arranged as a non-unitary structure (e.g., as a multi-wire helix). In some embodiments, pin 106 may be formed from a resilient metal. In some embodiments, pin 106 may be formed from a conductive material.

In some embodiments, body portion 110 of pin 106 is shaped substantially as an arc (e.g., as shown in FIG. 1A). The length and radius of curvature of the arc may be selected based on desired mechanical properties of pin 106 (e.g., a desired spring constant), desired dimensions of pin 106, or any of a number of other factors. Body portion 110 of pin 106 may have any of a number of other shapes instead of an arcuate shape, including other curves, multiple angled portions (e.g., a zig-zag), or a combination of shapes. Pin 106 may be formed from any of a number of materials, including material with a round cross-section (e.g., a round wire), material with a substantially flat cross-section (e.g., flat wire), or material with a varying cross-section. For example, in some embodiments, a round wire with a diameter of 100 microns, or a flat wire with dimensions of 50 microns by 500 microns, may be used.

Interposer 100 may include a first frame 114 having a first opening 116 extending from a first surface 118 of first frame 114 to a second surface 120 of first frame 114. Interposer 100 may include a second frame 122 having a second opening 124 extending from a first surface 126 of second frame 122 to a second surface 128 of second frame 122. Interposer 100 may include a body frame 130, disposed between second surface 120 of first frame 114 and first surface 126 of second frame 122. Body frame 130 may have a body opening 132 extending from a first surface 134 of body frame 130 to a second surface 134 of body frame 130. Body frame 130 may be coupled to each of first frame 114 and second frame 122 using a pressure sensitive adhesive (PSA) or other fastening mechanism.

As shown in FIG. 1A, in some embodiments, first end portion 108 of pin 106 may be disposed in first opening 116 of first frame 114, second end portion 112 of pin 106 may be disposed in second opening 124 of second frame 122, and body portion 110 of pin 106 may be captured or otherwise disposed in body opening 132 between first frame 114 and second frame 122. A portion of first end portion 108 of pin 106 may extend beyond first surface 118 of first frame 114 and a portion of second end portion 110 of pin 106 may extend beyond second surface 128 of second frame 122 (e.g., as shown in FIG. 1A).

FIG. 1A depicts interposer 100 positioned away from TE 102 and DUT 104. FIG. 1B depicts interposer 100 in operational contact with TE 102 and DUT 104. In FIG. 1B, interposer 100 may be positioned relative to TE 102 so that a tip of pin 106, proximate to first end portion 108, is in electrical contact with an electrical contact point 138 of TE 102. In use, interposer 100 may also be positioned relative to DUT 104 so that a tip of pin 106, proximate to second end portion 112, is in electrical contact with an electrical contact point 140 of DUT 104 to cause an electrical connection between TE 102 and DUT 104 through pin 106. As shown in FIG. 1B, positioning interposer 100 in operational contact with TE 102 and DUT 104 may cause a compressive force to be applied to pin 106. This compressive force may cause movement of first end portion 108 of pin 106 within first opening 116 and movement of second end portion 112 of pin 106 within second opening 124. The compressive force may further cause deformation of body portion 110 of pin 106 (e.g., as shown in FIG. 1B).

In some embodiments, body frame 130 may provide most of the load transfer ability of interposer 100, while first frame 114 and second frame 122 may provide relatively less stiffening to interposer 100. For example, body frame 130 may be thicker in some portions than first frame 114 or second frame 122, and thereby impart more stiffness. In some embodiments, body frame 130 may be formed of a non-conductive plastic, and first frame 114 and second frame 122 may be formed from a non-conductive polyimide or ceramic. In some embodiments, the materials used for body frame 130, first frame 114 and second frame 122 may be low cost materials. In some embodiments, due to its relative strength, body frame 130 may be used to mechanically attach interposer 100 to TE 102, DUT 104, or another fixture (e.g., via one or more bolts or clamps).

In some embodiments, first frame 114 and second frame 122 may be manufactured using lower tolerance manufacturing processes so that openings 116 and 124 may be precisely positioned and dimensioned, while body frame 130 may be manufactured using relatively higher tolerance manufacturing processes (resulting in, e.g., less precision in the positioning and dimensioning of body opening 132). For example, body frame 130 may be formed using a low resolution fused deposition modeling technique, or another low-resolution 3-D printing or other fabrication technique, while first frame 114 and second frame 122 may be formed using a higher resolution laser drilling or other technique. Thus, in some embodiments, the number of components of interposer 100 that need be formed using low tolerance manufacturing techniques may be reduced, while maintaining a desired accuracy and precision for the alignment and placement of pin 106 in order to provide good electrical connections between interposer 100 and TE 102 and/or DUT 104.

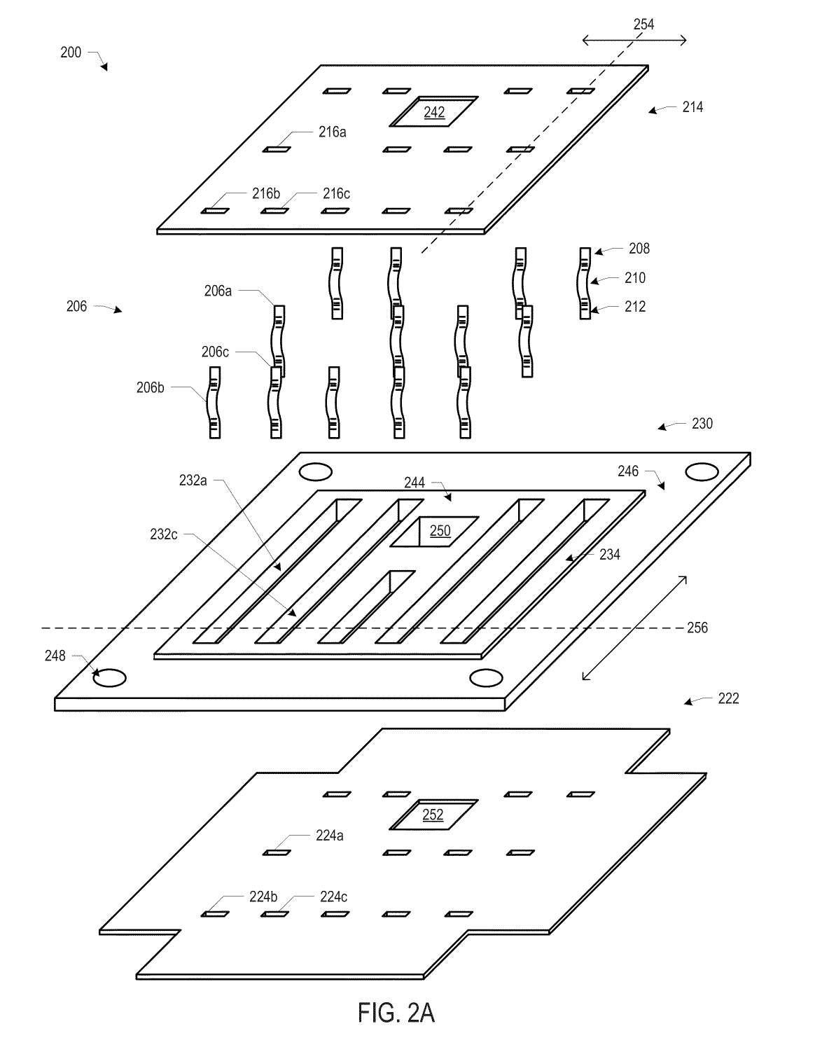

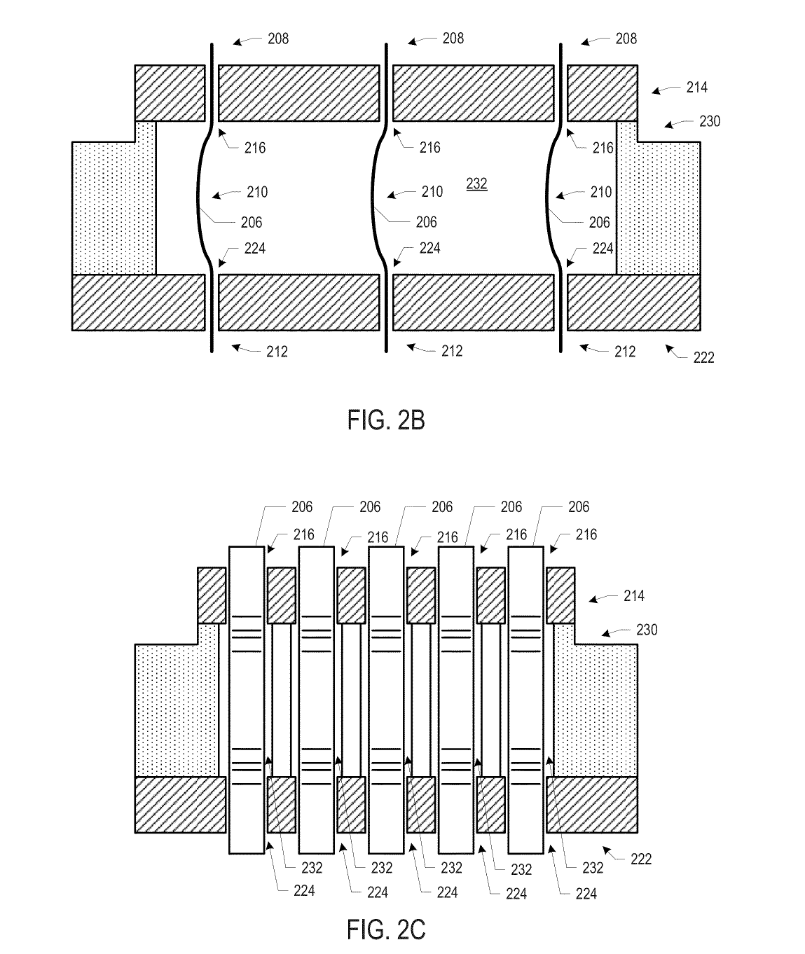

FIG. 2A illustrates an exploded perspective view of an interposer 200 with multiple pins 206, in accordance with some embodiments. Pins 206 may take the form of any of the pins described herein (e.g., pin 106 described above with reference to FIGS. 1A and 1B). Each of pins 206 may have a first end portion 208, a second end portion 212, and a body portion 210 disposed between first end portion 208 and second end portion 212.

Interposer 200 may include a first frame 214 having multiple openings 216 extending through first frame 214. Interposer 200 may include a second frame 222 having multiple openings 224 extending through second frame 222. Interposer 200 may include a body frame 230, disposed between first frame 214 and second frame 222. Body frame 230 may be coupled to each of first frame 214 and second frame 222 using a PSA or other fastening mechanism. In some embodiments, body frame 230 may have a center portion 244 and a perimeter portion 246 of different thicknesses, as shown in FIG. 2A. In some embodiments, body frame 230 may have a substantially uniform thickness. Body frame 230 may have multiple body openings 232 extending through body frame 230. As shown in FIG. 2A, one or more of body openings 232 may be formed as an oblong slot extending along a surface 234 of body frame 230. In some embodiments, two or more of the oblong slots forming body openings 232 may be parallel.

In some embodiments, openings 216 in first frame 214 may be arranged in a pattern that is substantially identical to a pattern in which openings 224 in second frame 222 are arranged. When interposer 200 is assembled, openings 216 in first frame 214 may substantially align with openings 224 in second frame 222. Each of openings 216 and 224 may also substantially align with one of body openings 232. In some embodiments, different openings 216 may align with one body opening 232. In some embodiments, different openings 216 may align with different body openings 232. For example, when interposer 200 is assembled, pin 206a may have a first end portion disposed in opening 216a of first frame 214, a second end portion disposed in opening 224a of second frame 222, and a body portion disposed in body opening 232a of body frame 230. Pin 206b may have a first end portion disposed in opening 216b of first frame 214, a second end portion disposed in opening 224b of second frame 222, and a body portion disposed in body opening 232a of body frame 230 (i.e., the same body opening in which the body portion of pin 206a is disposed). Pin 206c may have a first end portion disposed in opening 216c of first frame 214, a second end portion disposed in opening 224c of second frame 222, and a body portion disposed in body opening 232c of body frame 230 (i.e., a different body opening from the body opening 232a in which the body portions of pin 206a and 206b are disposed). As discussed above with reference to FIGS. 1A and 1B, when interposer 200 is assembled, the first end portions 208 of pins 206 may extend beyond first frame 214 and the second end portions 212 of pins 206 may extend beyond second frame 222.

First frame 214, body frame 230 and second frame 222 may each include one or more through-holes (242, 250 and 252, respectively). When interposer 200 is assembled, through-holes 242, 250 and 252 may align to provide a through-hole through interposer 200 that can accommodate surface features of TE or a DUT. In some embodiments, the outer dimensions of first frame 214 may substantially match the outer dimensions of center portion 244 of body frame 230 (e.g., as shown in FIG. 2A). In some embodiments, the outer dimensions of second frame 222 may substantially match the outer dimensions of perimeter portion 246 of body frame 230 (e.g., as shown in FIG. 2A). Body frame 230 may include one or more mounting holes 248, which may be used to mount interposer 200 to TE, a DUT, or another fixture during use.

FIG. 2B illustrates a cross-section side view of interposer 200 of FIG. 2A along section 254 (FIG. 2A). The ones of pins 206 shown are each disposed in a different opening 216 in first frame 214 and a different opening 224 in second frame 222, but are all disposed in a same body opening 232 (e.g., an oblong slot) in body frame 230. In some embodiments, each of pins 206 may have a longitudinal axis extending from first end portion 208 to second end portion 212, and each of pins 206 may be moveable in the direction of its longitudinal axis within its respective opening 216. Pins 206 may be moveable in the direction of their longitudinal axes prior to operational contact with TE or a DUT. In some embodiments, as discussed above with reference to FIG. 1B, operational contact between interposer 200 and a TE or DUT may cause a compressive force to be applied in a longitudinal direction to pins 206, which may cause deformation of body portions 210 of pins 206.

As shown in FIGS. 2A and 2B, pins 206 may be arranged in interposer 200 in a substantially parallel orientation. In particular, when a compressive force is applied to pins 206 (e.g., when interposer 200 is in operational contact with TE and/or a DUT), body portions 210 of pins 206 may deform in a substantially parallel manner. Maintaining pins 206 in a substantially parallel relation during use may reduce electrical interference between pins 206. In embodiments in which body openings 232 are formed as an oblong slot extending in a direction substantially perpendicular to longitudinal axes of pins 206 (e.g., as shown in FIGS. 2A and 2B), body portions 210 of pins 206 may be guided by the slot to deform substantially in the direction of the slot when a compressive force is applied. In some embodiments, the deformation of body portions 210 of pins 206 occurs substantially within a plane containing the longitudinal axes of pins 206. Body openings 232 may further operate to physically isolate different ones of pins 206 that are located in different body openings 232 to prevent inadvertent electrical contact. The orientation of pins 206 with respect to interposer 200 may also be maintained by a close fit between the dimensions of openings 216 and the dimensions of first end portions 208 of pins 206, and/or a close fit between the dimensions of openings 224 and the dimensions of second end portions 212 of pins 206.

FIG. 2C illustrates a cross-section side view of interposer 200 of FIG. 2A along section 256 (FIG. 2A). Pins 206 shown are each disposed in a different opening 216 in first frame 214, a different opening 224 in second frame 222, and a different body opening 232 (e.g., an oblong slot) in body frame 230. When a compressive force is applied to pins 206 (e.g., when interposer 200 is in operational contact with TE and/or a DUT), body portions 210 of pins 206 may deform in a substantially parallel manner (e.g., by arcing out of the plane of the page). In some embodiments, the widths of body openings 232 are larger than the widths of corresponding openings 216 in first frame 214 or corresponding openings 224 in second frame 222.

The fabrication of first frame 214, body frame 230, and second frame 222 may follow any of the approaches described above with respect to first frame 114, body frame 130, or second frame 122 of FIGS. 1A and 1B. In particular, body frame 230 may provide most of the load transfer ability of interposer 200, while first frame 214 and second frame 222 may provide relatively less stiffening to interposer 200. In some embodiments, first frame 214 and second frame 222 may be manufactured using lower tolerance manufacturing processes so that openings 216 and 224 may be precisely positioned and dimensioned, while body frame 230 may be manufactured using relatively higher tolerance manufacturing processes (resulting in, e.g., less precision in the positioning and dimensioning of body openings 232). For example, body frame 230 may be formed using a low resolution fused deposition modeling technique, or another low-resolution 3-D printing or other fabrication technique, while first frame 214 and second frame 222 may be formed using a higher resolution laser drilling or other technique. Moreover, the use of body openings 232 that accommodate more than one of pins 206 and need not be precisely sized to constraint the placement and orientation of pins 206 (e.g., the oblong slot) may advantageously reduce manufacturing complexity by allowing body frame 230 to be formed by a manufacturing process with a more relaxed tolerance requirement than existing interposers.

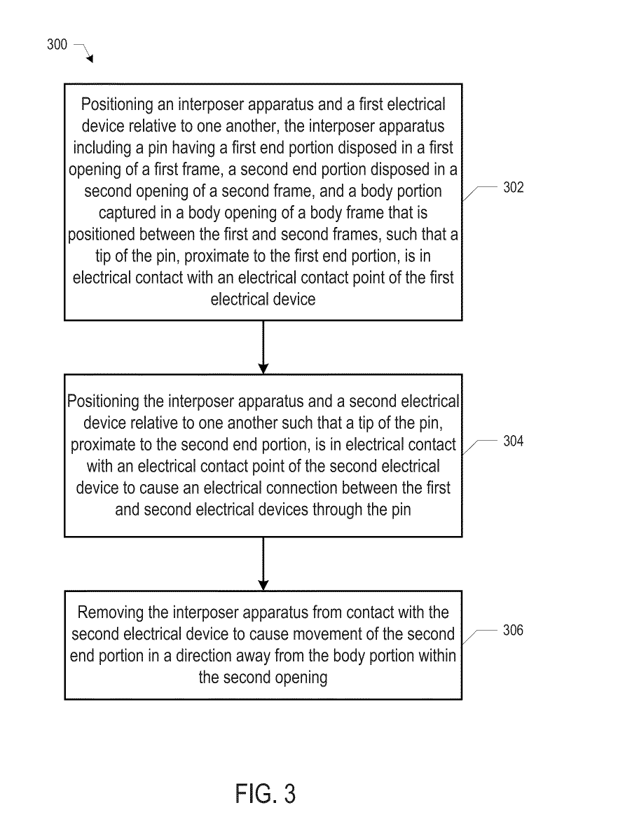

FIG. 3 is a flow diagram 300 of a method of positioning an interposer (such as interposer 100 of FIGS. 1A and 1B, or interposer 200 of FIGS. 2A-2C) relative to first and second electrical devices, in accordance with some embodiments. First and second electrical devices may correspond to, for example, TE and a DUT, or vice versa. In some embodiments, an interposer as disclosed herein may be used (e.g., in accordance with the method of FIG. 3) in non-device-testing applications to provide a temporary or otherwise detachable interconnect between two electrical devices. For example, an interposer may be used in a socket or other temporary attachment point on an original equipment manufacturer (OEM) device into which various components (e.g., PCBs) may be inserted.

At 302, an interposer apparatus and a first electrical device may be positioned relative to one another. The interposer apparatus may include a pin having a first end portion disposed in a first opening of a first frame, a second end portion disposed in a second opening of a second frame, and a body portion captured in a body opening of a body frame that is positioned between the first and second frames (e.g., interposer 100 of FIGS. 1A and 1B, or interposer 200 of FIGS. 2A-2C). The interposer apparatus and the first electrical device may be positioned such that a tip of the pin, proximate to the first end portion, is in electrical contact with an electrical contact point of the first electrical device. In some embodiments, 302 may include mechanically securing the interposer to the first electrical device (e.g., via mounting holes 248 of interposer 200 of FIGS. 2A-2C).

At 304, the interposer apparatus and a second electrical device may be positioned relative one another such that a tip of the pin, proximate to the second end portion, is in electrical contact with an electrical contact point of the second electrical device to cause an electrical connection between the first and second electrical devices through the pin. In this operational contact configuration, device testing or other device use may occur. In some embodiments, 304 may include mechanically securing the interposer to the second electrical device (e.g., via mounting holes 248 of interposer 200 of FIGS. 2A-2C).

In some embodiments, positioning the interposer apparatus and the first electrical device relative to one another (302) and positioning the interposer apparatus and the second electrical device relative to one another (304) may cause a compressive force to be applied to the pin to cause movement of the first end portion within the first opening and movement of the second end portion within the second opening. The compressive force may further cause deformation of the body portion of the pin. In embodiments in which the body opening includes an oblong slot extending in a direction substantially perpendicular to a longitudinal axis of the pin, the body portion of the pin may be guided by the slot to deform substantially in the direction of the slot. In some embodiments, the first and second end portions define a longitudinal axis of the pin and the deformation of the body portion of the pin occurs substantially within a plane containing the longitudinal axis.

In some embodiments, the pin may be a first pin and the interposer apparatus may further include a second pin (e.g., as discussed above with reference to interposer 200 of FIGS. 2A-2C). The second pin may have a first end portion, a body portion, and second end portion, and the body portion of the second pin may be captured in the body opening with the body portion of the first pin, the first end portion of the second pin may be disposed in an opening in the first frame different from the first opening, and the second end portion of the second pin may be disposed in an opening of the second frame different from the second opening. In some such embodiments, positioning the interposer apparatus and the first electrical device relative to one another (302) includes positioning a tip of the second pin proximate to the second end portion of the second pin in electrical contact with a second electrical contact point of the first electrical device. Positioning the interposer apparatus and the second electrical device relative to one another (304) may include positioning a tip of the second pin proximate to the first end portion of the second pin in electrical contact with a second electrical contact point of the second electrical device. In some embodiments, positioning the interposer apparatus and the first electrical device relative to one another (302) and positioning the interposer apparatus and the second electrical device relative to one another (304) may cause a compressive force to be applied to the first and second pins to cause substantially parallel deformation of the respective body portions of the first and second pins.

At 306, the interposer apparatus may be removed from contact with the second electrical device to cause movement of the second end portion in a direction away from the body.

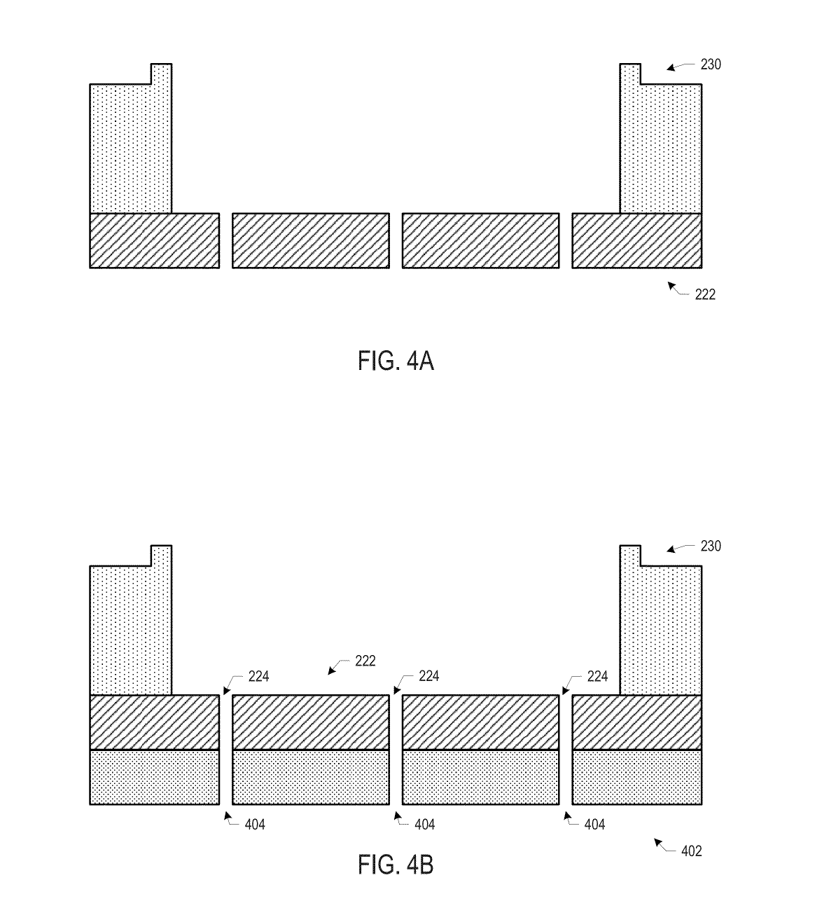

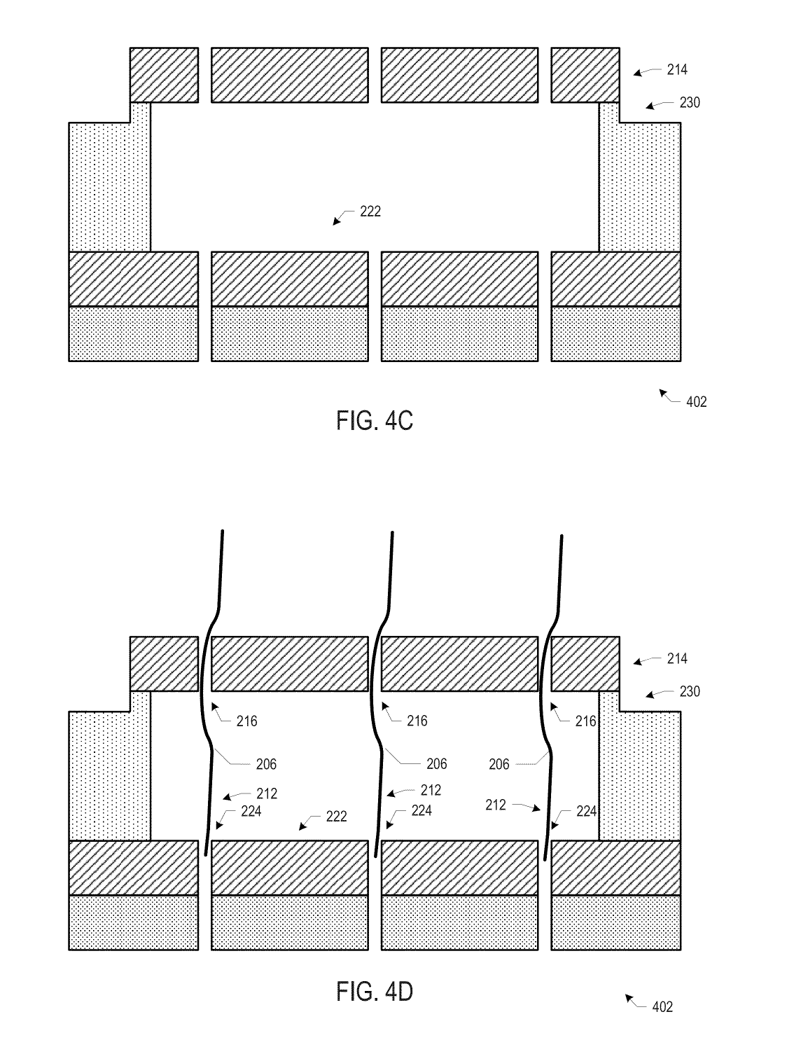

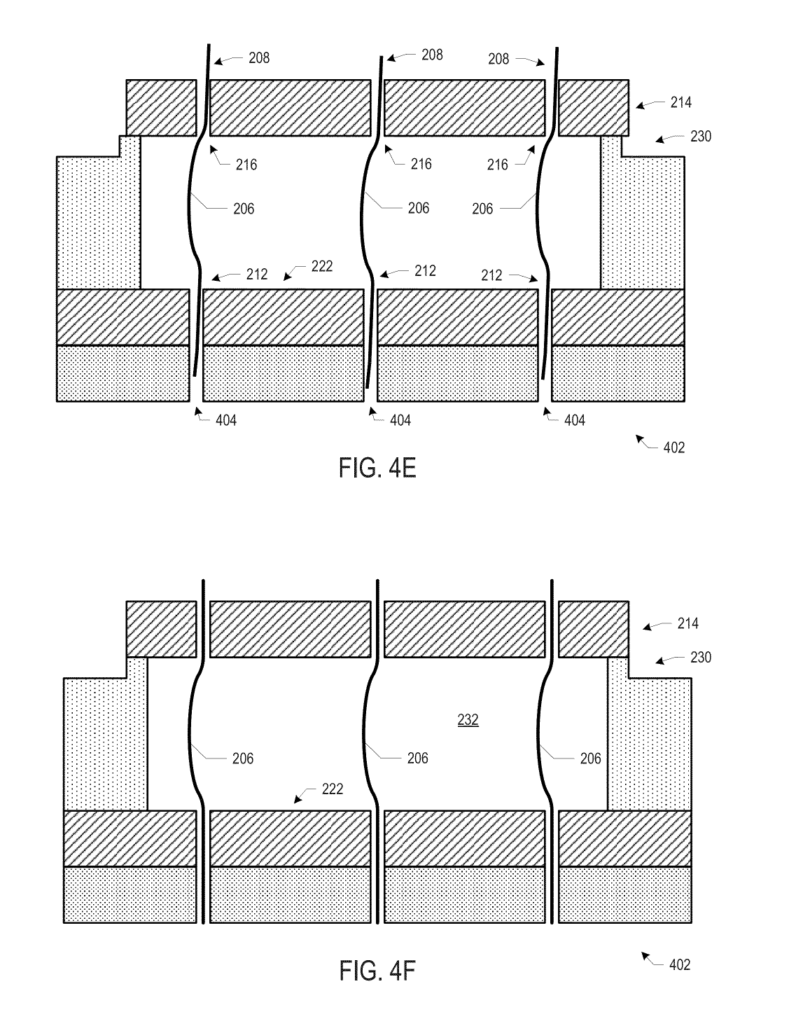

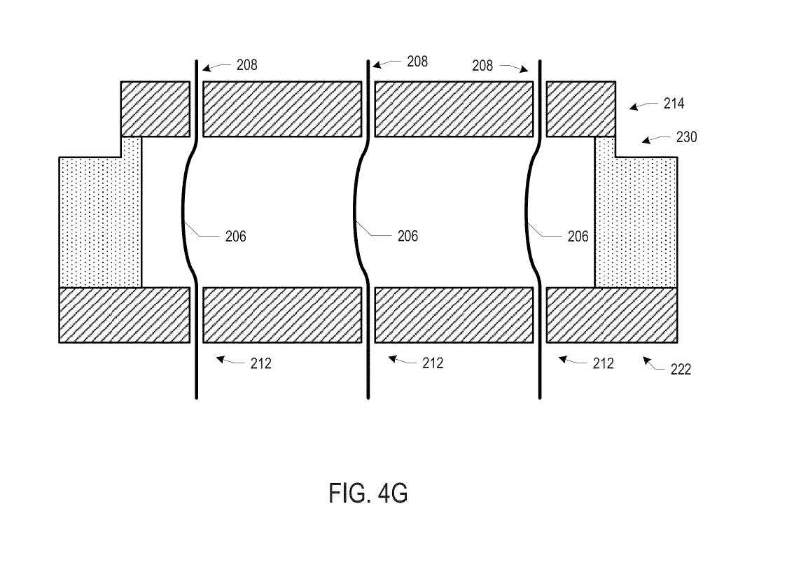

FIGS. 4A-4G schematically illustrate interposer 200 subsequent to various fabrication operations, in accordance with some embodiments. For illustrative purposes, the fabrication operations illustrated in FIGS. 4A-4G are described with reference to the fabrication of interposer 200 of FIGS. 2A-2C, but such operations may comport with any of the interposer embodiments described herein (e.g., the embodiments described in connection with FIGS. 1 and 3).

Referring to FIG. 4A, an interposer 200a is depicted subsequent to attaching second frame 222 to body frame 230. The attachment between second frame 222 and body frame 230 may be a permanent or semi-permanent coupling. For example, the attachment may be performed using glue, screws, or clamps. As discussed above with reference to FIGS. 2A-2C, the attachment may be via a PSA or other fastening mechanism.

Referring to FIG. 4B, an interposer 200b is depicted subsequent to attaching a jig 402 to second frame 222. Jig 402 may be made from a substantially rigid material, such as a plastic. Jig 402 may have multiple openings 404 extending through jig 402, which may align with openings 224 extending through second frame 222. In some embodiments, the attachment between jig 402 and second frame 222 may be a temporary attachment that may be detached at later fabrication operations, as described in detail below. For example, in some embodiments, the attachment between jig 402 and second frame 222 may be accomplished by screws or clamps.

Referring to FIG. 4C, an interposer 200c is depicted subsequent to attaching first frame 214 to body frame 230. In some embodiments, the attachment between first frame 214 and body frame 230 may be a temporary attachment that may be adjusted at later fabrication operations, as described in detail below. For example, in some embodiments, the attachment between first frame 214 and body frame 230 may be accomplished by screws or clamps. In some embodiments, first frame 214 may be simply positioned on top of body frame 230 so that its position relative to body frame 230 may be readily adjusted by a human or machine operator.

Referring to FIG. 4D, an interposer 200d is depicted subsequent to inserting pins 206 into openings 216 of first frame 214 and positioning second end portions 212 of pins 206 into openings 224 of second frame 222. In some embodiments, pins 206 may be manually inserted into openings 216 and 224. In some embodiments, pins 206 may be inserted into openings 216 and 224 by automated equipment. As shown in FIG. 4D, pins 206 may be inserted into openings 216 so that pins 206 are oriented in a substantially parallel manner.

Referring to FIG. 4E, an interposer 200e is depicted subsequent to adjusting first frame 214 by translating first frame 214 horizontally with reference to body frame 230. The adjustment of first frame 214 depicted in FIG. 4E is one of many adjustments that may be performed to help guide pins 206 through openings 216 of first frame 214 and position second end portions 212 of pins 206 into openings 404 of jig 402. Other adjustments that may be performed include a horizontal translation of first frame 214 in the opposite direction (e.g., to the left with reference to FIG. 4E), a vertical translation, a rotation, or any combination of adjustments. As shown in FIG. 4E, in some embodiments, second end portions 212 of pins 206 may be longer than first end portions 208 of pins 206. This may make it easier to position second end portions 212 of pins 206 into openings 224 during insertion of pins 206 and may help anchor second end portions 212 of pins 206 in openings 404 of jig 402.

Referring to FIG. 4F, an interposer 200f is depicted subsequent to attaching first frame 214 to body frame 230. This attachment may be performed once pins 206 have been fully inserted into interposer 200f and first frame 214 has been positioned in its desired final location. The attachment between first frame 214 and body frame 230 may be a permanent or semi-permanent coupling. For example, the attachment may be performed using glue, screws, or clamps. As discussed above with reference to FIGS. 2A-2C, the attachment may be via a PSA or other fastening mechanism.

Referring to FIG. 4G, an interposer 200g is depicted subsequent to detaching jig 402 from second frame 222. Interposer 200g may then be used in the form depicted, or, in some embodiments, first end portions 208 and/or second end portions 212 of pins 206 may be shortened so that they extend a uniform or other desired distance from second frame 222. In some embodiments, such shortening is performed by attaching, to the outward-facing surfaces of first frame 214 and/or second frame 222, jigs (not shown) whose thickness is approximately equal to the desired length of first end portions 208 and/or second end portions 212, respectively. A chemical or mechanical polishing process may then be applied to plane or otherwise adjust the protruding portions of first end portions 208 and/or second end portions 212 of pins 206 into alignment with the jigs, after which the jigs may be removed.

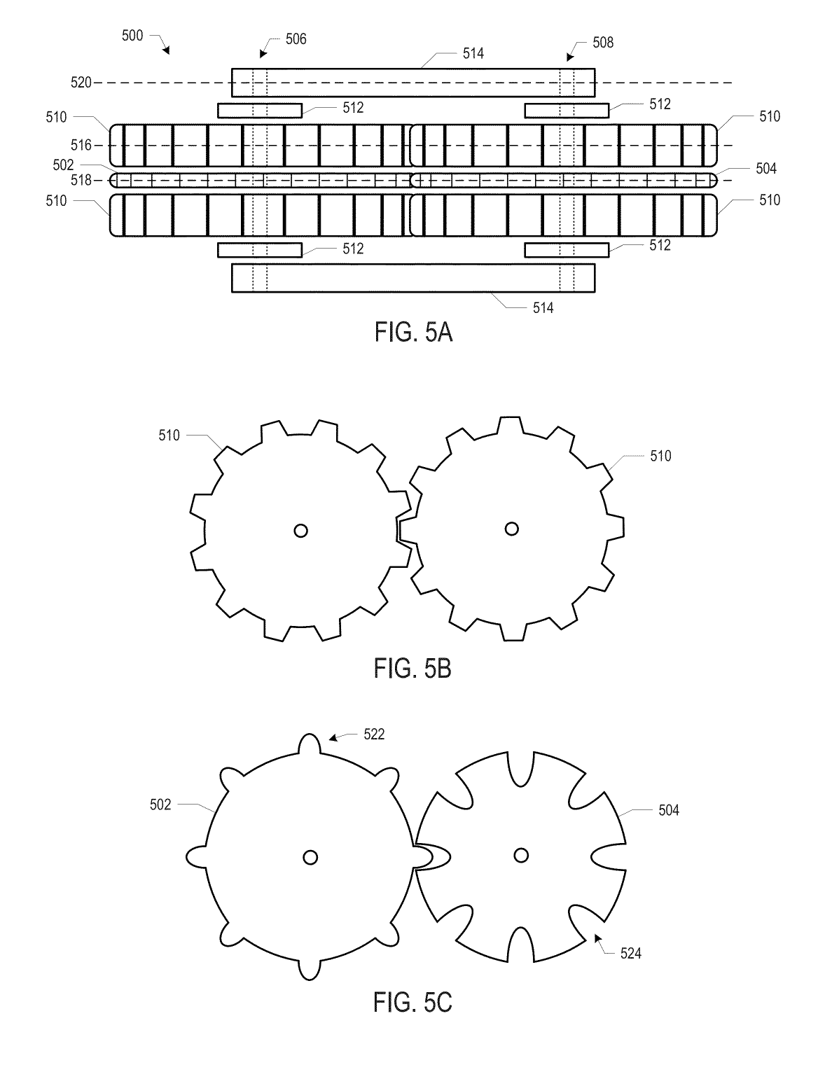

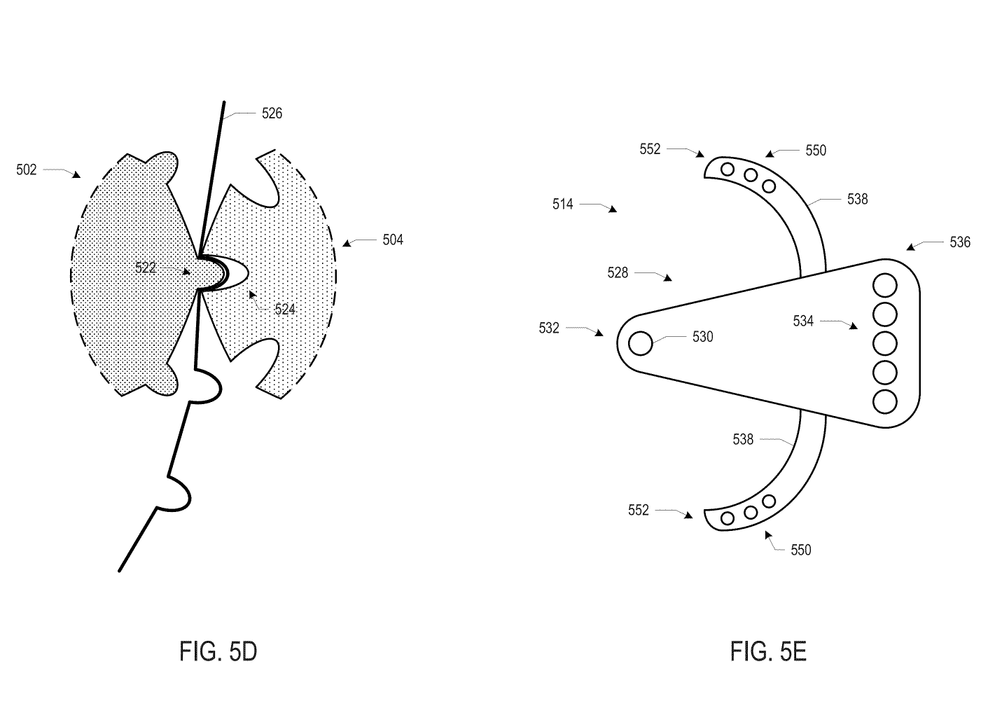

Turning now to FIG. 5A, a side view of a pin fabrication assembly 500 is illustrated, in accordance with some embodiments. Assembly 500 may be used to fabricate pins for the interposers disclosed herein (e.g., pin 106 of FIGS. 1A and 1B and pins 206 of FIGS. 2A-2C). Assembly 500 may be used in any of a number of manufacturing processes other than the fabrication of pins for an interposer, including die-forming, die-cutting and stamping processes.

Assembly 500 may include first rotary die 502 and second rotary die 504 (which may be, for example, spur gears). In some embodiments, first rotary die 502 may have a tooth pattern that provides a male die, and second rotary die 504 may have a tooth pattern that provides a female die. The tooth patterns of first rotary die 502 and second rotary die 504 may be complementary such that first rotary die 502 and second rotary die 504 may be mating dies. First rotary die 502 may be rotatable about a first axis 506, and second rotary die 504 may be rotatable about a second axis 508. First rotary die 502 may be flanked by a pair of outer gears 510, which may mate with a corresponding pair of outer gears 510 flanking second rotary die 504. Bearings 512 may be disposed between outer gears 510 and support elements 514.

In use, first rotary die 502 and second rotary die 504 may be mated and rotated about their respective axes (e.g., at a substantially constant angular speed), and a material may be fed between first rotary die 502 and second rotary die 504 during rotation to cause compression of the material between the male die and the female die. Thus, in some embodiments, feeding and forming of material may be simultaneous and/or continuous.

In some embodiments, the male die and the female die cooperate to form an arcuate shape in the material. Material formed with an arcuate shape may be used to form pins for an interposer (e.g., interposer 100 of FIGS. 1A and 1B or interposer 200 of FIGS. 2A-2C). In some embodiments, the material may be a wire having a substantially circular cross-section profile, a wire having a substantially flat cross-section profile, a sheet material, or other material. In some embodiments, a distance between first axis 506 and second axis 508 may be adjustable (e.g., by adjusting support elements 514, as described below). Adjusting the distance between first axis 506 and second axis 508 may be advantageous for accommodating material of various thicknesses.

FIG. 5B illustrates a cross-section top view of two mating outer gears 510 along section 516 of pin fabrication assembly 500 of FIG. 5A, in accordance with some embodiments. In assembly 500, outer gears 510 may be secured to first rotary die 502 and second rotary die 504, and may be driven at the center of outer gears 510 by a belt or other drive mechanism. Outer gears 510 may also provide a guide for material fed into the interface between first rotary die 502 and second rotary die 504.

FIG. 5C illustrates a cross-section top view of first rotary die 502 and second rotary die 504 along section 518 of pin fabrication assembly 500 of FIG. 5A, in accordance with some embodiments. First rotary die 502 may include a tooth pattern with a number of arcuate male dies 522. Second rotary die 504 may include a tooth pattern with a number of arcuate female dies 524. In use, a material is fed between first rotary die 502 and second rotary die 504 and is compressed between mating male and female dies to form an arcuate shape.

FIG. 5D is a detailed view of a portion of first rotary die 502 and second rotary die 504 in pin fabrication assembly 500 of FIG. 5A during operation, in accordance with some embodiments. Material 526 may be fed into the interface between male die 522 and female die 524, shaped, and fed out as shown. In some embodiments, the tooth pattern of first rotary die 502 further provides a first cutting surface (e.g., a wedge or other cutting surface, not shown) and the tooth pattern of second rotary die 504 further provides a second cutting surface (e.g., a wedge, a flat surface, or other surface, not shown), and the first and second cutting surfaces cooperate to cut the material after the material has been compressed between female die 524 and male die 522.

FIG. 5E is a cross-section top view of support element 514 along section 520 of pin fabrication assembly 500 of FIG. 5A, in accordance with some embodiments. Support element 514 includes a body 528 with a first hole 530 disposed at a first end 532 of body 528 and a plurality of second holes 534 disposed at a second end 536 of body 528. A first axle member (e.g., an elongate bolt, not shown) may be disposed in first hole 530 to act as first axis 506. A second axle member (e.g., an elongate bolt, not shown) may be disposed in one of second holes 534 to act as second axis 508. Mirror image support elements 514 may be oriented in assembly 500 as shown in FIG. 5A. Support element 514 may also include two arms 538 with one or more holes 540 disposed at the distance ends 542 of arms 538. In use, a fastener may be disposed in one of holes 540 and extended through to the corresponding hole in the mirror image support element 514 to secure assembly 500 against twisting.

The rotational forming apparatus and techniques disclosed herein may have advantages over traditional forming processes. For example, existing technologies typically rely on die forming by translating an active die toward a counterpart die. In each build cycle of such a process, raw material is fed in to a forming tool and then die formed, requiring precise control of the feeding amount as well as discrete force or displacement control of the active die. Such step-function-like movement of raw material and dies may create negative dynamic impact to the manufacturing process by introducing inaccuracy at forming. The potential inaccuracies may be more difficult to reduce when the dimension of feeding material is too small to effectively use alignment features. Inaccuracies during forming may be a major source of low percent yield in final manufactured products. Thus, by using a comparatively uniform displacement force (e.g., to maintain a constant angular speed of the rotating dies), the rotational forming apparatus and techniques disclosed herein may advantageously reduce the positional inaccuracy caused by the dynamic impact of dies and material, thus enabling high speed forming and low cost manufacturing.

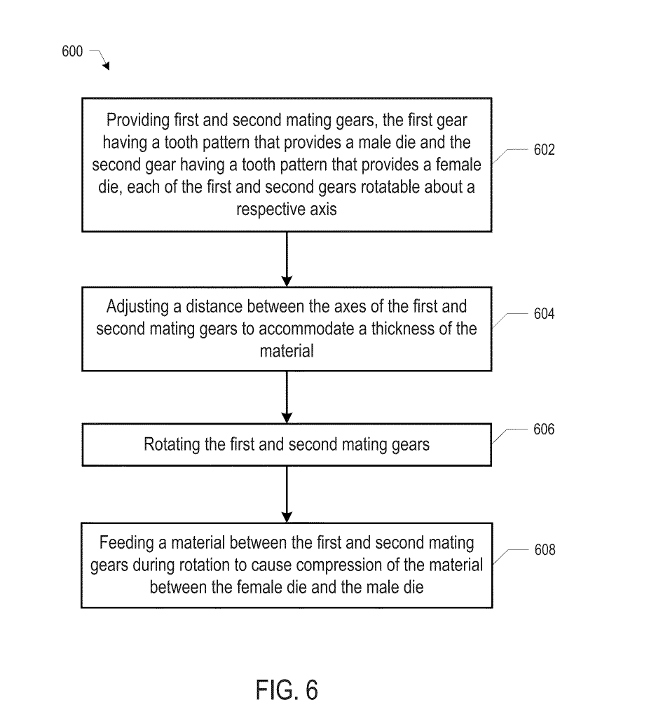

FIG. 6 is a flow diagram 600 of a method of fabricating a pin for an interposer (e.g., interposer 100 of FIGS. 1A and 1B, or interposer 200 of FIGS. 2A-2C), in accordance with some embodiments. The method of flow diagram 600 may describe some embodiments of pin fabrication assembly 500 (FIGS. 5A-5E).

At 602, first and second rotary dies may be provided. The first gear may have a tooth pattern that provides a male die and the second gear may have a tooth pattern that provides a female die. Each of the first and second rotary dies may be rotatable about a respective axis. In some embodiments, the first and second rotary dies may be each attached to mating spur gears. At 604, a distance between the axes of the first and second rotary dies may be adjusted to accommodate a thickness of the material.

At 606, the first and second rotary dies may be rotated. In some embodiments, 606 includes rotating the first and second rotary dies at a substantially constant angular speed. At 608, a material may be fed between the first and second rotary dies during rotation to cause compression of the material between the female die and the male die. In some embodiments, the tooth pattern of the first rotary die further provides a first cutting surface and the tooth pattern of the second rotary die further provides a second cutting surface, with the first and second cutting surfaces cooperative to cut the material after the material has been compressed between the female die and the male die.

Various operations are described herein as multiple discrete operations in turn, in a manner that is most helpful in understanding the claimed subject matter. However, the order of description should not be construed as to imply that these operations are necessarily order dependent.

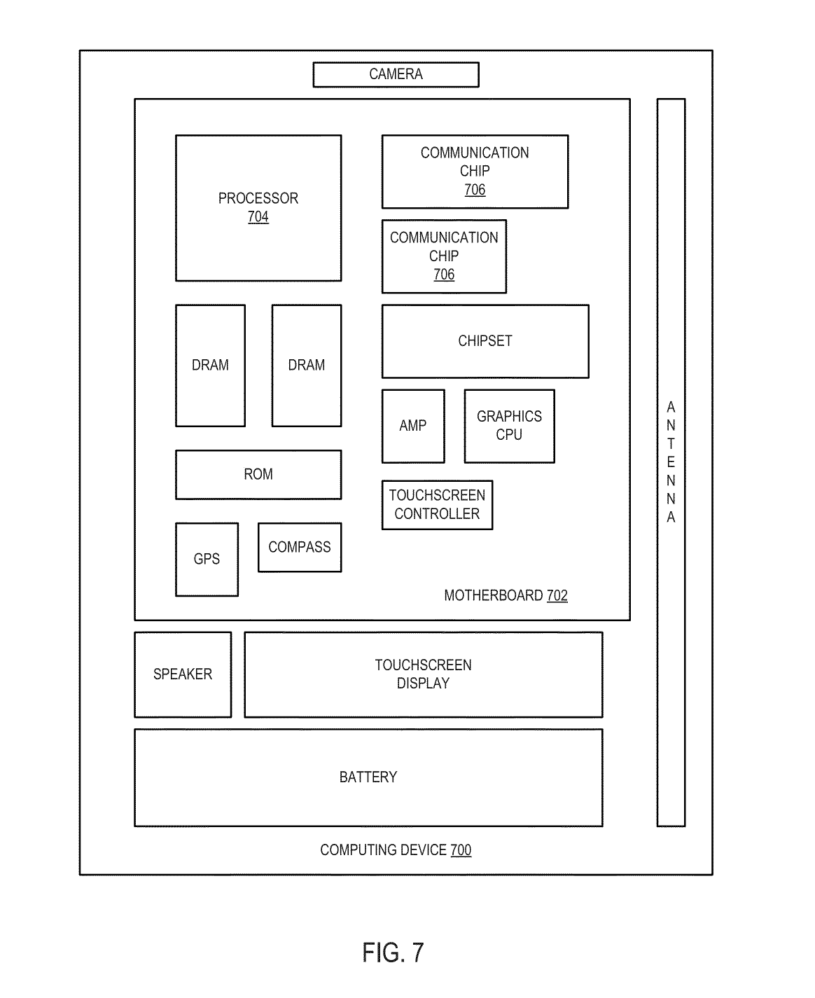

Embodiments of the present disclosure may be implemented into a system using any suitable hardware and/or software to configure as desired. FIG. 7 schematically illustrates a computing device 700 in accordance with one implementation. In some embodiments, an interposer as disclosed herein may be used to test one or more components of computing device 700. In some embodiments, an interposer as disclosed herein may be used as an interconnect between one or more components of computing device 700.

The computing device 700 may house a board such as motherboard 702. The motherboard 702 may include a number of components, including but not limited to a processor 704 and at least one communication chip 706. The processor 704 may be physically and electrically coupled to the motherboard 702. In some implementations, the at least one communication chip 706 may also be physically and electrically coupled to the motherboard 702. In further implementations, the communication chip 706 may be part of the processor 704. The term “processor” may refer to any device or portion of a device that processes electronic data from registers and/or memory to transform that electronic data into other electronic data that may be stored in registers and/or memory.

Depending on its applications, computing device 700 may include other components that may or may not be physically and electrically coupled to the motherboard 702. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 706 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 706 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 706 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 706 may operate in accordance with other wireless protocols in other embodiments.

The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The communication chip 706 may also include an IC package assembly that may be tested or interconnected with another component using an interposer as described herein. In further implementations, another component (e.g., memory device or other integrated circuit device) housed within the computing device 700 may contain an IC package assembly that may be tested or interconnected with another component using an interposer as described herein.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data. In some embodiments, the techniques described herein are implemented in a high-performance computing device. In some embodiments, the techniques described herein are implemented in handheld computing devices.

The above description of illustrated implementations, including what is described in the Abstract, is not intended to be exhaustive or to limit the present disclosure to the precise forms disclosed. While specific implementations and examples are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a pin having a first end portion, a body portion, and a second end portion, the body portion being disposed between the first end portion and the second end portion;
a first frame having a first opening extending from a first surface of the first frame to a second surface of the first frame;
a second frame having a second opening extending from a first surface of the second frame to a second surface of the second frame; and
a body frame, disposed between the second surface of the first frame and the first surface of the second frame, having a body opening extending from a first surface of the body frame to a second surface of the body frame;
wherein the first end portion of the pin is disposed in the first opening, the second end portion of the pin is disposed in the second opening, and the body portion of the pin is disposed in the body opening between the first and second frames.

2. The apparatus of claim 1, wherein the body opening includes an oblong slot extending along the first surface of the body frame.

3. The apparatus of claim 2, wherein the pin is a first pin, and the apparatus further comprises:
a second pin having a first end portion, a body portion, and second end portion, wherein the body portion of the second pin is disposed in the slot with the body portion of the first pin, the first end portion of the second pin is disposed in an opening in the first frame different from the first opening, and the second end portion of the second pin is disposed in an opening of the second frame different from the second opening.

4. The apparatus of claim 1, further comprising a second pin having a first end portion, a body portion, and second end portion, wherein the body portion of the second pin is disposed in a second body opening in the body frame different from the first body opening, the first end portion of the second pin is disposed in an opening in the first frame different from the first opening, and the second end portion of the second pin is disposed in an opening of the second frame different from the second opening.

5. The apparatus of claim 4, wherein the first body opening includes a first oblong slot extending along the first surface of the body frame and the second body opening includes a second oblong slot extending along the first surface of the body frame parallel to the first slot.

6. The apparatus of claim 1, wherein the pin has a longitudinal axis extending from the first end portion to the second end portion, and the first end portion of the pin is moveable in a direction of the longitudinal axis within the first opening.

7. The apparatus of claim 1, wherein the first opening is one of a plurality of openings arranged in a pattern in the first frame and the second opening is one of a plurality of openings arranged in a pattern in the second frame that is substantially identical to the pattern in the first frame.

8. The apparatus of claim 1, wherein the body portion of the first pin is shaped substantially as an arc.

9. The apparatus of claim 1, wherein a portion of the first end portion of the pin extends beyond the first surface of the first frame and a portion of the second end portion of the pin extends beyond the second surface of the second frame.

10. The apparatus of claim 1, wherein the first pin is a materially contiguous, unitary structure.

11. The apparatus of claim 1, wherein the body portion of the pin is shaped so as to be captured in the body opening between the first and second frames.

12. A method, comprising:
positioning an interposer apparatus and a first electrical device relative to one another, the interposer apparatus comprising a pin having a first end portion disposed in a first opening of a first frame, a second end portion disposed in a second opening of a second frame, and a body portion disposed in a body opening of a body frame that is positioned between the first and second frames, such that a tip of the pin, proximate to the first end portion, is in electrical contact with an electrical contact point of the first electrical device; and
positioning the interposer apparatus and a second electrical device relative to one another such that a tip of the pin, proximate to the second end portion, is in electrical contact with an electrical contact point of the second electrical device to cause an electrical connection between the first and second electrical devices through the pin.

13. The method of claim 12, wherein positioning the interposer apparatus and the first electrical device relative to one another and positioning the interposer apparatus and the second electrical device relative to one another cause a compressive force to be applied to the pin to cause movement of the first end portion within the first opening and movement of the second end portion within the second opening.

14. The method of claim 13, wherein the compressive force further causes deformation of the body portion of the pin.

15. The method of claim 14, wherein:
the body opening comprises an oblong slot extending in a direction substantially perpendicular to a longitudinal axis of the pin; and
the body portion of the pin is guided by the slot to deform substantially in the direction of the slot.

16. The method of claim 14, wherein the first and second end portions define a longitudinal axis of the first pin and the deformation of the body portion of the pin occurs substantially within a plane containing the longitudinal axis.

17. The method of claim 12, further comprising:
removing the interposer apparatus from contact with the second electrical device to cause movement of the second end portion in a direction away from the body portion within the second opening.

18. The method of claim 12, wherein:
the pin is a first pin;
the interposer apparatus further comprises a second pin having a first end portion, a body portion, and second end portion, wherein the body portion of the second pin is disposed in the body opening with the body portion of the first pin, the first end portion of the second pin is disposed in an opening in the first frame different from the first opening, and the second end portion of the second pin is disposed in an opening of the second frame different from the second opening;
positioning the interposer apparatus and the first electrical device relative to one another comprises positioning a tip of the second pin, proximate to the first end portion of the second pin, in electrical contact with a second electrical contact point of the first electrical device; and
positioning the interposer apparatus and the second electrical device relative to one another comprises positioning a tip of the second pin, proximate to the second end portion of the second pin, in electrical contact with a second electrical contact point of the second electrical device.

19. The method of claim 18, wherein positioning the interposer apparatus and the first electrical device relative to one another and positioning the interposer apparatus and the second electrical device relative to one another cause a compressive force to be applied to the first and second pins to cause substantially parallel deformation of the respective body portions of the first and second pins.

20. The method of claim 19, wherein the first electrical device is a device-under-test and the second electrical device includes test equipment.

21. The method of claim 12, wherein the body portion of the pin is shaped so as to be captured in the body opening between the first and second frames.

22. A method of fabricating a pin for an interposer apparatus, the method comprising:
providing first and second rotary dies, the first rotary die having a tooth pattern that provides a male die and the second rotary die having a tooth pattern that provides a female die, each of the first and second rotary dies rotatable about a respective axis;
rotating the first and second rotary dies; and
feeding a material between the first and second rotary dies during rotation to cause compression of the material between the female die and the male die.

23. The method of claim 22, wherein the first and second mating gears are attached to spur gears.

24. The method of claim 22, wherein rotating the first and second rotary dies comprises rotating the first and second rotary dies at a substantially constant angular speed.

25. The method of claim 22, wherein the tooth pattern of the first rotary die further provides a first cutting surface and the tooth pattern of the second rotary die further provides a second cutting surface, the first and second cutting surfaces cooperative to cut the material after the material has been compressed between the female die and the male die.

26. The method of claim 22, further comprising adjusting a distance between the axes of the first and second rotary dies to accommodate a thickness of the material.

27. The method of claim 22, wherein the material is a wire having a substantially circular cross-section profile or a substantially flat cross-section profile.

28. The method of claim 22, wherein the male die and the female die cooperate to form an arcuate shape in the material.
